(19) United States
(12) Patent Application Publication
(10) Pub. No.: US 2023/0186462 A1
(43) Pub. Date: Jun. 15, 2023

(54) APPARATUS AND METHOD FOR INSPECTING CONTAINERS

(71) Applicant: KRONES AG, Neutraubling (DE)

(72) Inventors: Thorsten GUT, Neutraubling (DE); Thomas BOCK, Hemau (DE)

(21) Appl. No.: 18/082,410

(22) Filed: Dec. 15, 2022

(30) Foreign Application Priority Data
Dec. 15, 2021 (DE) 10 2021 133 276.1

(51) Int. Cl. G06T 7/00; G06T 7/564; G06T 17/10

(52) U.S. Cl. CPC G06T 7/001; G06T 7/564; G06T 17/10; G01N 21/90

(57) ABSTRACT

Disclosed is a method for inspecting containers, wherein the containers are transported along a predetermined transport path using a transport device and are inspected using an inspection device, wherein the inspection device records at least one spatially resolved image of a container to be inspected using an image recording device and an image evaluation device evaluates this image. According to the invention, data of a model of this container are used to evaluate this image.

### BACKGROUND OF THE INVENTION

The present invention relates to an apparatus and a method for inspecting containers, wherein the containers are transported along a predetermined transport path by means of a transport device and are inspected by means of an inspection device. Apparatus and methods for inspecting containers have been known in the prior art for a long time. Usually, the inspection device takes at least one spatially resolved image of a container to be inspected and an image evaluation device evaluates this image.

With various inspection systems it is necessary to create the bottle contours in 2D or 3D in the software. While this is still reasonably “simple” for 2D contours (contour of the bottle in transmitted light), it becomes very computationally intensive for 3D data, which is required, for example, when processing the bottle surface for a 360° label inspection.

The current systems either scan a real bottle or have to evaluate the contour from an image recording (by means of brightness differences) or have to be “traced” manually by means of lines. The basis is always a real bottle. This means that further inaccuracies can flow into the desired “reference contour”.

WO 2019/185184 A1 discloses an apparatus for optical position detection of transported containers. For this purpose, an image recording device for recording spatially resolved images and a background element with a predetermined pattern are provided.

The present invention is based on the object of overcoming the disadvantages known from the prior art and providing a customer- and user-friendly apparatus and method for inspecting containers which reduce the inaccuracies as far as possible by using a real reference bottle in bottle inspection systems.

### SUMMARY OF THE INVENTION

In a method according to the invention for inspecting containers, wherein the containers are transported along a predetermined transport path by means of a transport device and are inspected by means of an inspection device, the inspection device records at least one spatially resolved image of a container to be inspected by means of an image recording device and an image evaluation device evaluates this image. The transport device can be a conveyor belt or a transport chain.

According to the invention, data from a model of this container is used to evaluate this image.

In other words, not a real image of a container is used as a reference to evaluate the captured image, but data available from the model of the container are used. In this way, inaccuracies in the reading of the reference contour are eliminated.

Containers are understood to be bottles made in particular of glass, plastic, pulp, metal or plastic preforms.

Preferably the image is taken and preferably the images are taken during transport. Preferably, the image is captured while the container is moved along the transport path. Preferably, the container is not at least partially, and preferably during the entire time the image is being captured, stationary in a recording position.

Preferably, several images are taken and data of the model of this container are preferably used for the evaluation of these images. Preferably, the container is exposed for image recording, wherein preferably at least one and preferably several illumination devices can be provided for this purpose.

A model of the container means in particular a virtual model of the container, which was preferably not (even not partially) generated from a real container. This offers the advantage that a real container does not first have to be captured, for example by a camera, in order to generate a reference model. Preferably, the model is a model of the outer wall of at least one area of the container and especially preferably the entire container.

This offers the advantage of a much simpler set-up of the apparatus for inspecting the containers, which can also be carried out beforehand in the house where the inspection apparatus is manufactured, instead of only at the customer's or operator's premises with real containers.

Preferably, for the evaluation of a recorded image, no data of a reference model are used, which was collected for a real container or is derived from it.

Furthermore, this advantageously eliminates the need for semi-automatic or manual learning of the bottle contour, for example in bottle sorting or foreign bottle detection, or semi-automatic or manual learning of the processing, for example in 360° label inspection.

The proposed method further offers the advantage of easy retrofitting of new bottle types at the customer's site or at the operator's site of the container inspection apparatus. Retrofitting can be done by replacing the data of the previous model of the old container type with data of a model of the container of the new container type. Therefore, time-consuming learning of the new bottle type can also be avoided during retrofitting.

Furthermore, complaints can be advantageously avoided.

Preferably, the model of the container is a (purely computer-generated), in particular three-dimensional, construction model of the container, and especially preferably a model that was constructed to (at least indirectly) create the container (to be inspected). For example, the model can be a CAD model (CAD abbreviation for “computer-aided design”). It is also conceivable that the data of the model are (in particular only) data derived from the design model or data generated purely by means of computer-based design, which in particular has no data generated by means of capturing a real container or object. The model could be a wireframe model, a surface model and/or a volume model and/or a triangle mesh.

Preferably, data used for the design and/or development of the container and/or for the manufacture of a container production and/or container treatment apparatus may be used. For example, the data of a model associated with the container to be inspected could be used for the data of the model of the container to be inspected, for example, for the production of blow moulds for this container for a blow moulding machine and/or for the production of an injection mould for the injection moulding of plastic preforms corresponding to this container. For example, the inner contour of the blow moulds for a blow moulding machine corresponds to the outer contour of the containers to be produced from them.

It is also conceivable that the data of the model includes, in addition to data of a virtual model (such as a CAD model), also data of a real model or data generated by capturing a real object or area of a container, such as photorealistic data. For example, the data of the model could be composed (inter alia or exclusively) of data of a 3D CAD model of a container and photorealistic data related to a label of the container.

Preferably, a database is provided on which data of a model of a plurality of containers are stored. The database can be stored on an external and/or non-volatile storage device in relation to the apparatus for inspecting the containers. The storage device may be cloud-based. It is conceivable that the apparatus for inspecting containers accesses the storage device in particular via the Internet (and/or via a public and/or private network, in particular at least partially wired and/or wireless) in order to retrieve the data of the model.

The external server is, for example, a backend, in particular of a container inspection apparatus manufacturer or a service provider, wherein the server is set up to manage data of the model or the model of the container and, in particular, data of a plurality of models or a plurality of models of (in particular different) containers.

The model and/or the data of the model can also contain a configuration of the container, such as a label and/or a closure of the container, or data characteristic thereof.

The data of the model may be data related to the entire model (including its equipment and/or parts of the equipment of the container or excluding the equipment of the container).

However, it is also conceivable that the data of the model are merely parts (such as an equipment) or components or an area of the container, such as a mouth area or a bottom area of the container or a side wall area of the container.

So preferably labels of the model can be compared with real labels.

In particular, the model is a model of at least one area of the container. It is conceivable that the model is not a model of the entire container and/or its equipment, but of only one area of the container and/or only one piece of equipment of the container. It is also conceivable that the model is composed of a plurality of models of different areas of the container and/or different equipment elements of the container. For example, a first model could be provided for the container and a further model for a label. These two models could be combined to provide a model for the container to be inspected.

In other words, the data of the model can be characteristic for (including or exclusively) a container type and/or an equipment and/or each equipment of the container to be inspected. It is also conceivable that the evaluation of the image only uses data of a model section which, in particular, essentially corresponds to the area to be inspected.

In a preferred method, the data of the model are three-dimensional data which are characteristic for the model of this container. The model can be a model created or generated (in particular purely) by means of an application for virtual product development, for example a CAD model. Preferably, at least parts of the model are purely virtually generated data and particularly preferably, the entire model of the container are purely virtually generated data (i.e. a model generated by means of a virtual product development application).

This offers the advantage that these data can be used for a variety of different container controls or in different detection units. In particular, this offers the advantage that a container control can be quickly changed over, for example, when equipment is changed, without having to repeatedly generate a model in a time-consuming manner, which must at least be monitored and/or accompanied by an operator.

Preferably, the data of the model and/or the model are characteristic of container parameters which are selected from a group comprising a (total) height of the container, a (bottom and/or main body and/or mouth rim) diameter of the container, a (nominal) volume of the container, a container geometry, in particular a course of the container neck, a bottom area, a container material, a container material (of the main body and/or of an equipment of the container), (at least or exactly) one filling material assigned to the container, an equipment of the container, a closure of the container, a mouthpiece of the container, a label assignment for the container, an equipment assignment for the container and the like as well as combinations thereof.

In a preferred method, a reference model of the container is created (preferably by means of a, in particular processor-based, model creation device) on the basis of the data, which is used to evaluate the captured image. This reference model of the container can be a three-dimensional and/or a two-dimensional model. For example, the reference model could be a reference model for a 2D or 3D bottle contour, or a reference model for an (at least partial and/or preferably complete) processing of the bottle surface (for example for a 360° label inspection). It is also conceivable that the two-dimensional reference model is a top view and/or a perspective view of the three-dimensional model and/or a cross-section and/or a projection and/or a side view of the three-dimensional model.

Preferably, the reference model is compared with the captured image, in particular with the data of this image.

In a preferred method, at least one evaluation variable to be used for evaluating the captured image is automatically determined on the basis of the data of the model. In particular, an automatic parameterisation can be carried out on the basis of the data of the model and each captured image can be evaluated by means of this parameterisation or using the at least one evaluation variable. Preferably, automatic parameterisation can be performed using a 3D bottle model.

It is also conceivable that several evaluation variables are determined and used to evaluate the recorded image. The evaluation variables are thus preferably determined only by means of the data of the model, without using data of a real container.

The evaluation variable can be a variable that is characteristic for a parameterisation for an (intended) container check and/or equipment check and/or a container sorting, for example for a contour to be checked (along a preferably predefined cross-sectional plane in relation to a predefined spatial orientation of the container), selection of an ROI (abbreviation for “region of interest”), a colour value or several colour values and the like.

This offers the advantage that, in contrast to the method known from the prior art, data relating to a real reference container does not first have to be recorded and the recorded image of the real reference container analysed in order to carry out a parameterisation and, based on this, a parameterisation has to be carried out by a user.

In contrast, it is proposed that at least one and preferably all evaluation variables to be used for evaluating the captured image are determined automatically on the basis of the data of the model, in particular without any required user input. However, it is also conceivable that the automatically determined evaluation variables are suggested to a user or a setter, for example, by outputting them to the user or the setter by means of an output device, and the user or the setter can change the evaluation variable(s) and thereby, for example, make a readjustment.

For example, in the case of container sorting or container inspection based on a container contour, it can already be specified that at least one evaluation variable is a characteristic variable for a container contour, which is automatically determined based on the data of the model of the container. If the container to be inspected is to be changed (e.g. by changing the type of container and/or equipment) or if, for example, a further type of container to be inspected is to be added, the at least one (new) evaluation variable can be determined automatically based on data of a model in relation to the changed container to be inspected.

Preferably, the type of evaluation (e.g. an inspection task) can be specified independently of a specific container (e.g. by a setter or an operator). For this purpose, it can be specified (for example by a setter or an operator, for example by instructions for processing the data of the model of the container, in particular in a changeable manner, which can be stored on an in particular non-volatile memory device) in which way an evaluation variable is determined based on specified data of a model of the container to be inspected. This offers the advantage that when a container type is changed, a corresponding image evaluation (by changing the data of the model) can be automatically adapted as well.

Preferably, the evaluation variable(s) is/are stored on a non-volatile memory device. Preferably, the non-volatile memory device is a (particularly fixed and/or non-destructively detachable) component of the image evaluation device. However, it is also conceivable that a data transmission device, in particular (at least partially or in its entirety) wireless and/or (at least partially or in its entirety) wire-bound, is provided, by means of which the evaluation variables and/or the data of the model of the container are transmitted (or can be transmitted) from the memory device to the image evaluation device.

In a preferred method, (at least) one synthetic image of a (2D and/or) 3D model of the container is created at a predetermined position in space, in particular a position that can be selected (by a setter or an operator). Preferably, a plurality of such synthetic images is created and used in particular for the evaluation of the captured image.

Preferably, an inspection area and in particular an inspection position (in particular in relation to the transport device and/or the image recording device(s) and/or in relation to a world coordinate system) can be set (by a setter or an operator). Preferably, the synthetic image is created depending on the position in space and/or the inspection area and/or the inspection position.

Preferably, the (at least one) synthetic image (or the plurality of synthetic images) is used at least in sections and/or as a calculation basis for the reference model and/or for evaluating the captured image.

Preferably, at least one image generation parameter and particularly preferably a plurality of image generation parameters for generating the at least one synthetic image or the plurality of synthetic images can be preset or set (by a setter or an operator). For example, an input device can be provided via which these image generation parameters can be entered or selected.

The image generation parameter may be an illumination parameter such as, for example, a number of illumination devices (such as number of light sources) and/or a (respective) position and/or an emitted light spectrum and/or an illumination area and/or an illumination type and/or an illumination angle of a (particularly virtual) illumination device (such as a light source).

The image generation parameter can be an image recording parameter such as a type (such as black/white or coloured) and/or a number and/or a position and/or a (respective) acquisition angle and/or an acquisition direction and/or a field of view of a (particularly virtual) illumination device.

For example, the image generation parameters can be used to set from which and from how many illumination devices the (virtual) container is illuminated and from which virtual cameras and from where a synthetic image of the (virtual) container is generated.

This offers the advantage that the structure and the type of image recording of the inspection device can be simulated by the selection of the image generation parameters. This means that the synthetic image can be used for direct comparison with the recorded image of the inspection device, in particular without rescaling and/or (perspective) distortion or rectification.

Preferably, at least one image is rendered based on the data of the model of the container, wherein the rendered image is used to evaluate the captured image. Preferably, the rendering is based on (predefined and preferably operator selectable or predefinable) material parameters (related to the container and/or an equipment of the container) and/or at least one or a plurality of image generation parameters (such as the above mentioned image illumination parameters and/or image recording parameters, e.g. number and position of light sources).

Preferably, (for the generation of a rendered image) a (synthetic and/or perspective) recording or image can be generated from a (predefined or by an operator predefinable or selectable) 3D scene and used for the evaluation of the image. Preferably, a (virtual) transport device and/or further (virtual) components of the inspection device can be part of the 3D scene.

It is also conceivable that a photorealistic (in particular two-dimensional) background image is used to generate the (synthetic and/or rendered) image. In this case, a representation of a background image recorded by the image recording device that is as close to reality as possible can be achieved.

Preferably, an artificial image of the 3D model is created with the parameters of the camera (and used to evaluate the captured image). You get an artificial image with all the same effects (lens distortion etc . . . ) as if the image had really been taken with the camera.

Preferably, based on the data of the model of the container, a representation of the model that is as close to reality as possible and/or a representation of the model that is as close to photo-reality as possible is generated, which is preferably used as a reference model for evaluating the captured image. For this purpose, the model of the container can be textured (in particular on the basis of predefinable texture parameters). Preferably, the evaluation of the image is based on a (at least sectional) texturing of the model of the container. In particular, at least one texture image is generated for this purpose on the basis of the data of the model and preferably on the basis of further texture parameters. A photo-realistic and/or a synthetic texture can be used for texturing.

Such texturing offers the advantage that even less detailed 3D models can be represented as realistically as possible and can thus be compared with the captured image to be evaluated in a particularly computationally efficient and thus particularly fast manner. This is particularly important because a transport device is preferably used that transports at least 5,000 containers to be inspected per hour (to and from the image recording device) or is suitable and intended for this purpose.

Preferably, the data of the model of the container comprises a quantity characteristic of an alignment (or orientation) of the container. Preferably, the alignment of the container is taken into account for the evaluation of the captured image. For example, the model of the container can be transformed, such as translated, scaled, rotated and/or also deformed (e.g. tapered, twisted, sheared and the like), in particular depending on its alignment.

Preferably, the alignment of the model of the container is compared with an alignment of the container to be inspected (in relation to the transport device and/or a camera position and/or the camera orientation) in order to evaluate the image.

Preferably, the alignment (or orientation) of the model and the orientation of the inspected container or the image taken from it are aligned with each other. In particular, for the evaluation of the captured image, the (3D) model and the orientation (or alignment) of the associated (or captured) images must refer to the same coordinate system.

It is conceivable, for example, that the data of the model are processed in such a way (in particular before the evaluation is carried out) that the orientation or alignment of the model is adapted to the orientation or alignment of the container to be inspected or the image taken from it and, in particular, brought into agreement.

This allows an essentially instant comparison of the captured image with the data from the model.

For the correct image size in the camera image, a calibration pixel per millimetre is preferred.

In a preferred method, a calibration of the image capture or the captured image, in particular a size calibration, is performed. Preferably, an essentially (correct or real) image size in the captured image can be determined on the basis of the calibration performed. For example, an imaging scale of the image capturing device can be determined by a calibration. For example, the calibration can be used to determine the real extent to which a (predefined) number of pixels of an object (such as the container) depicted in the captured image corresponds.

Preferably, at least one spatial or geometric expansion variable (such as a height and/or a width and/or a diameter) of the container can be determined from the captured image of the container on the basis of the calibration.

Calibration can be carried out in several ways:

Preferably, a (predefined) calibration body is used for calibration, of which an expansion variable of interest, such as a height, is known. Preferably, the image recording device (e.g. the camera) takes an image of the calibration body. By evaluation with the respective image recording device (e.g. camera) and in particular by comparison of the calibration body depicted in the recorded image with the expansion variable or with the dimension of the real calibration body, an imaging scale (in particular with respect to a predetermined relative arrangement of the image recording device and a container to be inspected) can be determined.

It is conceivable that the data of the model of the container and/or (vice versa) the captured image (at least in areas) is scaled based on the calibration and/or based on the determined imaging scale.

Additionally or alternatively, a comparison of the captured image or the real image and the (3D) data (of the model), preferably in height, can be made for calibration. Preferably, for example, a real image of a real bottle is recorded with the detection unit (or image recording device) and then the ideal values of the 3D bottle drawing are preferably “zoomed in” in height.

Additionally or alternatively, a calibration can be performed based on a measurement of typical features (e.g. conveyor belt chain) as a reference value. Preferably, an image of an element (for example, the transport device) of the inspection device is captured with the image recording device for calibration. The recorded image is preferably compared with a (predefined or measured) expansion variable of the (real) element and preferably an imaging scale is determined from this, which can be used and in particular is used for calibration. Preferably, the element can be an element of the inspection device that was also (at least partially) imaged when the image of the inspected container was taken. For example, it can be an element of the inspection device that is visible in the background of the captured image.

In a preferred method, a calibrated image recording device (e.g. camera) is used. It is also conceivable that a calibration of the image recording device is carried out. Preferably, a position and, in particular, a relative arrangement and/or a relative alignment between the image recording device and the container to be inspected and/or the inspected container (in particular at the time of image recording) can be derived from the calibration of the image recording device (and/or by the calibration of the image recording device). Particularly preferably, a position of the image recording device in the world coordinate system can be determined.

This offers the advantage that an alignment or orientation of the container depicted in the captured image can be determined. From this, a more precise evaluation of the recorded image can be carried out based on a predetermined and, in particular, on a previously known alignment or orientation of the model of the container, since the size ratios and/or the relative alignments between the inspected container (or the depicted container in the recorded image) and the model of the container (or the data of the model) can be taken into account in the evaluation of the recorded image. This enables a better and simpler pixel-by-pixel or area-by-area comparison of the captured image and, for example, a (synthetic) image determined based on the data of the model.

Preferably, by using a calibrated image recording device (e.g. camera), the position of the image recording device (e.g. camera) in the world coordinate system is known and, for example, a synthetic image of the (3D) model of the container can be created at any position in space. The contour obtained from this can then serve as a reference, for example.

In a preferred method, a calibration of the (reference) model determined on the basis of the data is determined with respect to the captured image.

Preferably, a perspective distortion and/or rotation and/or scaling of the imaged container and/or of the data of the model and/or of the reference model and/or of the model is carried out on the basis of the calibration and/or an imaging scale and/or relative (angular and/or distance) arrangement between the (real) inspected container and the container imaged in the captured image. Preferably, the alignment and/or the size of the model of the container is also taken into account.

In a preferred method, a size of the model of the container that is invariant with respect to spatial operations, in particular with respect to scalings, rotations and/or translations, is used for the evaluation of the captured image (in particular, for example, as an evaluation variable). This offers the advantage that no calibration (for example of the image recording device) is required. For example, a contour of the container can be generated directly from the 3D model and evaluated by suitable methods which are invariant to scaling, rotation and translation. No calibration is necessary for this. Contour recognition would be an example of this.

In a preferred method, the inspection device outputs at least one value that is characteristic for the inspected container. This can be a value for a contour, e.g. for foreign container detection, a value for a container type, a value for a label and/or for a label inspection, a value for a fitting, a value for a fitting inspection, a value for a mouth, a value for a side wall, inspection results therefor and combinations thereof. This offers the advantage that a further treatment step of the container (such as rejection and/or packaging) can be derived from this value.

In a preferred method, the image evaluation performs a container sorting and/or a container inspection selected from a group of container inspections (or inspection objects) including foreign container detection, equipment inspection, label inspection, mouth inspection, sidewall inspection, side walk detection of plastic preforms and the like.

It is also conceivable that (additionally or alternatively) a contour of the inspected container is determined by means of false exposure (“over-radiation”) by means of the inspection device.

In a preferred method, dimensions for a 360° processing of the container are obtained from the data, wherein preferably these dimensions being selected from a group of dimensions comprising a height of the container, a diameter of the container, a mouth cross-section of the container, a lateral contour of a mouth region of the container, a lateral contour of a neck of the container and/or the like, and combinations thereof.

The contour obtained from this can then serve as a reference. For example, the captured image can be evaluated as a reference by means of the contour obtained, for example by comparing a contour determined from the captured image (corresponding to the reference contour) with the (reference) contour obtained.

In a preferred method, the data are loaded from a memory device into the evaluation device. The memory device can in particular be a storage device according to one of the embodiments described above.

It is conceivable that a plurality of models of containers (each different from the other) is stored (in the database) on the memory device. It is conceivable that the image evaluation device selects (exactly) one model or the data of the model from the plurality of models on the basis of the recorded image, in particular automatically, and evaluates the image on this basis (to determine a characteristic value for the inspected container).

It is conceivable that on the basis of the captured image, an (automatic) assignment of data of a model (or the model) from a plurality of models (or data of a plurality of models) takes place. In other words, (exactly) one model is preferably determined and/or identified from the recorded image, which is particularly preferably used subsequently for the evaluation of the image.

However, it is also conceivable (additionally or alternatively) that an operator, in particular via an input device, makes a selection (of exactly one model) or a preselection of several models from the plurality of stored models. It is conceivable that such a (pre-)selection triggers the transfer or loading of the data of the respective model or models into the image evaluation device. The input device may be a stationary or mobile input device located at the site of the inspection device. However, it is also conceivable that the input device is located at a different place and, in particular, not in the same hall as the inspection device and the operator triggers or sets a selection of the model and/or a loading or transfer of the model and/or an inspection object to be carried out by the inspection device by means of remote access (remote control).

In a preferred method, the object points of the 3D model are projected back into the image recording device (e.g. camera) and preferably a characteristic value and a (in particular real) colour value is assigned to an object point. In this way, the 3D model can be given the real colour and, for example, a development of it can be generated (360° ETK).

In a preferred method, a contour of the container is generated from a 3D model of the container. This can be used, for example, to evaluate the recorded image, e.g. by means of pixel-by-pixel and/or section-by-section comparison. The use of a contour of the container offers the advantage, particularly in the case of (essentially) rotationally symmetrical containers, that this size is invariant to rotations of the container (about its longitudinal axis).

The present invention is further directed to an apparatus for inspecting containers, comprising a transport device which transports the containers along a predetermined transport path and an inspection device which inspects the containers, wherein the inspection device comprises an image recording device which records at least one spatially resolved image of a container to be inspected and an image evaluation device is provided which evaluates this image.

According to the invention, the image evaluation device uses data from a model of this container to evaluate this image.

Preferably, a data transmission device is provided which feeds this data to the image evaluation device (preferably at least in sections via a private network and/or public network, such as the Internet).

The apparatus for inspecting containers can be configured, suitable and/or intended to carry out all the process steps or features described above in connection with the method for inspecting containers, either individually or in combination with one another. Conversely, the method described above, in particular the apparatus for inspecting containers described in the context of the method, may have and/or use all the features described in connection with the apparatus, individually or in combination with one another.

In an advantageous embodiment, the apparatus has a model creation device, in particular processor-based, which creates a three-dimensional model of a reference container using the data. Preferably, the three-dimensional model and/or (two-dimensional) projections or sections or views of this three-dimensional model are used to evaluate the recorded image (for example by means of comparison).

It is thus also proposed in the context of the apparatus according to the invention that an automatic parameterisation or an automatic set-up of an image evaluation and/or an automatic set-up of an inspection object to be performed by the apparatus is carried out (in particular exclusively) on the basis of data of a model of the container. In particular, no real image is used to generate a reference model (for performing the image evaluation of further containers). Therefore, in particular, no data of a real container for use as a reference model for an image evaluation of inspected containers is stored in the image evaluation device or a memory device connected thereto for data exchange.

The present invention is further directed to a computer program or computer program product comprising program means, in particular a program code, which represents or codes at least individual method steps of the method according to the invention, in particular the method steps carried out by means of the model creation device and/or the image evaluation device, and preferably one of the described preferred embodiments, and is designed to be executed by a processor device.

The present invention is further directed to a data storage on which at least one embodiment of the computer program according to the invention or a preferred embodiment of the computer program is stored.

### BRIEF DESCRIPTION OF THE DRAWINGS

Further advantages and embodiments can be seen in the accompanying drawings: In the drawings:

FIG. 1 shows a schematic representation of an apparatus for inspecting containers according to an embodiment of the invention;

FIG. 2 shows a representation of a model of a container and a database in which the data of the models of several containers are stored;

FIG. 3 shows a representation of a model of a container together with an alignment of the model; and

FIG. 4 shows a captured image to illustrate the evaluation of this image.

### DETAILED DESCRIPTION OF THE INVENTION

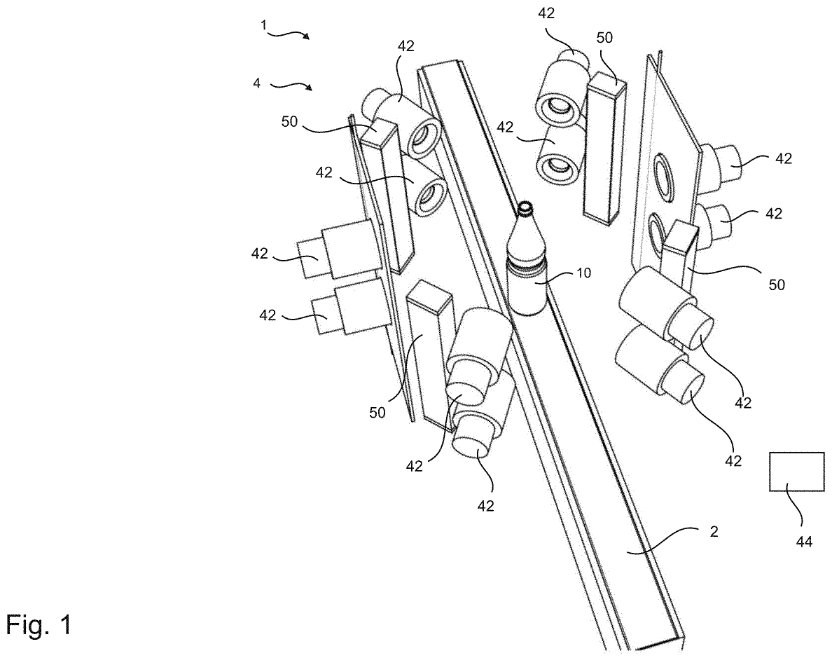

FIG. 1 shows an apparatus 1 for inspecting containers 10 according to an embodiment of the invention. The reference sign 2 indicates a transport device which guides the containers 10 to be inspected along a (predefined) transport path to the inspection device 4 and discharges the containers here from the inspection device.

The inspection device 4 can have one or more image recording devices 42, such as cameras. In FIG. 1, for example, 12 image recording devices are arranged, which are arranged here on two different inspection levels, wherein the image recording devices of one inspection level record images of a lower container area, while the image recording devices 42 of the other inspection level record images of an upper container area of a container 10 to be inspected.

The image recording devices 42 can be arranged in such a way that several or all of these image recording devices 42 each capture at least one image of the container to be inspected while it is essentially in at least one inspection position or while it is in a (fixed) predetermined inspection area. Preferably, the container to be inspected is in (transport) motion while the image is being captured by the image recording device(s) 42. Preferably, the transport speed of the container 10 to be inspected is not or not significantly reduced for image recording and, in particular, the container is not stopped for this purpose.

Furthermore, the apparatus 1 comprises an image evaluation device 44, in particular processor-based, which evaluates the captured image on the basis of data of a model of the container 10.

The apparatus 1 may further comprise at least one or more illumination device(s) 50 for illuminating the container to be inspected.

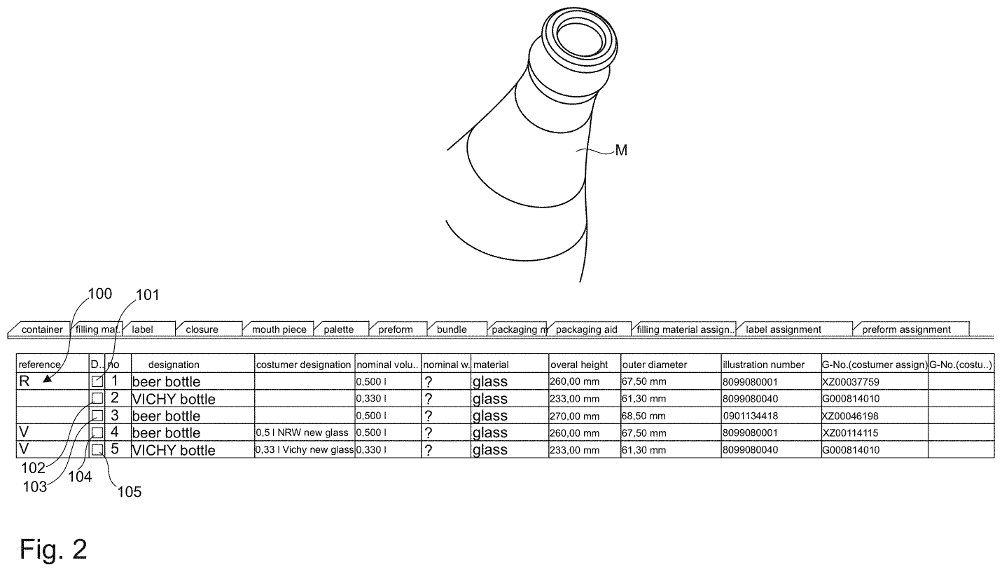

FIG. 2 shows a representation of a model M of a container 10 and a database in which the data of the models of several containers are stored. For example, (available) data of a model of a container can be stored in a database, such as an SAP database. For example, it could be the database of a manufacturer of blow moulding machines and/or a manufacturer of blow moulding moulds and/or a manufacturer of inspection equipment or a service provider thereof, in which customer objects (e.g. for administration) are stored in the form of 3D models.

For example, bottles that are available digitally and in particular in 3D can be directly imported into the evaluation software (or transferred to the image evaluation device) and preferably processed in the respective recognition units.

Typical detections can be:
contour for bottle sorting and/or foreign bottle detection;
sidewall inspection

The current sidewall inspection composes the evaluation image from several views. For this purpose, however, a contour must always be determined in the first step by means of false exposure, (“over-illumination”). With the ideal data, the determination of the contour and/or the evaluation image is significantly more accurate and subject to fewer errors.
360° label inspection
The correct dimensions of the container (height, diameter, lateral contour) for the following 360° processing can be obtained directly from the 3D data.
Preform sidewall detection
These preforms are also available in 3D and can also be loaded into the evaluation software as a target contour.

The “loading” of a model or data of one (or more models) of a container is done in particular by a corresponding software library such as Halcon, PatMax (Cognex) etc.. This software processes the 3D data accordingly so that it can be used in the following evaluation algorithms.

In the database a plurality of data sets relating to (in each case) a container (to be manufactured and/or inspected) can be stored. In the database shown in FIG. 2, for example, the data sets 101, 102, 103, 104 and 105 are stored for different (customer) containers. A data record associated with a container can be uniquely identified, in particular, by means of a reference identification 100 and/or a designation.

Furthermore, a data set associated with a container (to be manufactured and/or inspected) may include a customer designation of the container and/or a customer identifier such as a customer number.

Preferably, a data set associated with a container (to be manufactured and/or inspected) comprises, in addition to the data of a model of the container, properties and/or characteristics of the container (to be manufactured and/or identified), which may be selected from a group comprising a (nominal) volume, a (nominal) weight, a material, a (total) height, an (outer) and/or (inner) diameter and the like, and combinations thereof.

A data set assigned to a container (to be manufactured and/or inspected) can, in addition to the data of a model of the container, also comprise data that are characteristic of a filling material, an equipment of the container such as a label, a closure, a mouthpiece, a pallet, a preform, a bundle, a packaging material, a packaging aid, a filling material assignment, an equipment assignment, such as a label assignment, and/or a preform assignment.

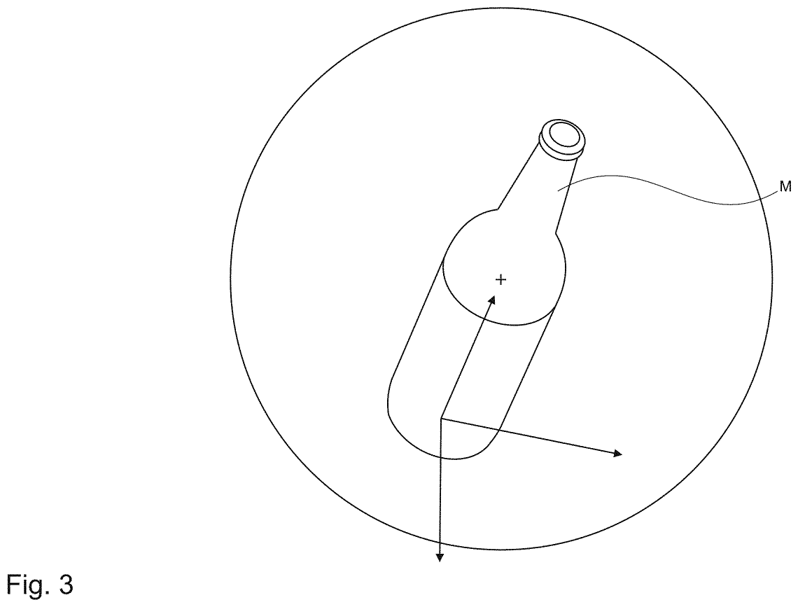

FIG. 3 shows a representation of a model M of a container together with an alignment of the model, which is represented by a coordinate system. This allows the evaluation of a recorded image to be precisely adapted to the alignment of the container to be inspected. For this purpose, data of the model can be processed, for example by rotation, in such a way that the alignment of the model is adapted to the alignment of the container to be inspected or to the alignment of the container on the recorded image. This enables a direct comparison of the model with the captured image without having the image data to rotate or the like.

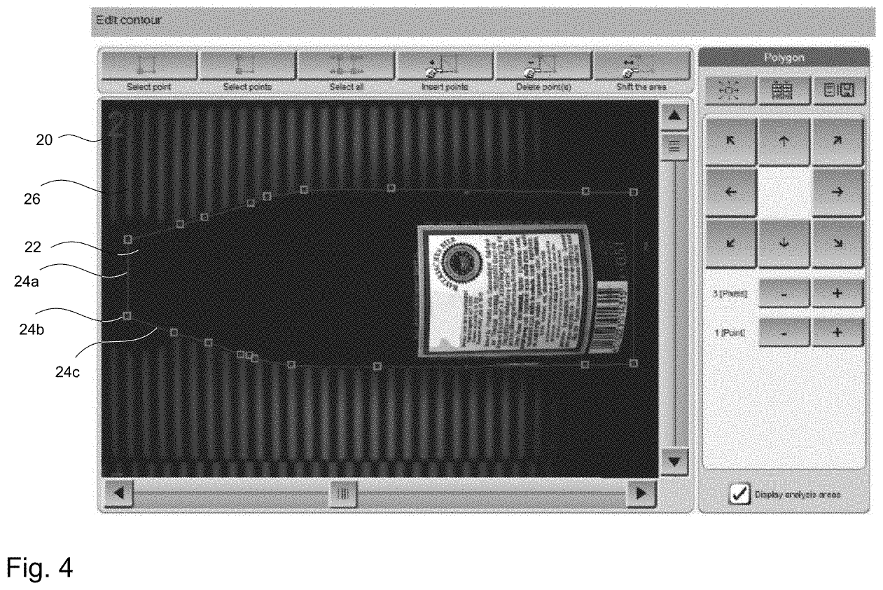

FIG. 4 shows an image 20 recorded by an inspection device 4, in particular by an image recording device 42 such as a camera, to illustrate the evaluation of this image 20.

Such a captured image 20 is usually parameterised for evaluation, for example by generating a contour line 24a, 24b and 24c by comparing the container 22 in the foreground of the image with a (here striped) illustrated background 26 of the captured image 20.

By determining the (relative) position of the nodes 24b and/or the extension and/or relative (angular) relationships and/or lengths of individual sections of the contour line 24a, 24c to one another and comparing them with the contour generated, for example, from the data of a model of the container, it is possible, for example, to draw conclusions about a particular type of container.

The applicant reserves the right to claim all features disclosed in the application documents as essential to the invention, provided they are individually or in combination new compared to the prior art. Furthermore, it is pointed out that the individual figures also describe features which may be advantageous in themselves. The skilled person immediately recognises that a certain feature described in a figure can also be advantageous without adopting further features from this figure. Furthermore, the skilled person recognises that advantages can also result from a combination of several features shown in individual figures or in different figures.

### LIST OF REFERENCE SIGNS

1 apparatus

2 transport device

4 inspection device

10 container

20 captured image

22 illustrated container to be inspected

24a-c container contour

26 illustrated background

42 image recording device

44 image evaluation device

50 illumination device

100 reference identification

101-105 data sets

M model

1. An method for inspecting containers, wherein the containers being transported along a predetermined transport path using a transport device and being inspected using an inspection device, wherein the inspection device records at least one spatially resolved image of a container to be inspected using an image recording device and an image evaluation device evaluating this image, wherein
data of a model of this container are used for evaluating this image.

2. The method according to claim 1,
wherein
the data of the model are three-dimensional data characteristic of the model of this container.

3. The method according to claim 1,
wherein
a reference model of the container is created on the basis of the data, which is used to evaluate the captured image.

4. The method according to claim 1,
wherein
at least one evaluation variable to be used for evaluating the captured image is automatically determined on the basis of the data of the model.

5. The method according to claim 1,
a synthetic image of a 3D model of the container is created at a predetermined selectable position in space.

6. The method according to claim 1,
wherein
a size of the model of the container which is invariant with respect to spatial operations, is used to evaluate the recorded image.

7. The method according to claim 1,
wherein
the inspection device outputs at least one value which is characteristic of the inspected container.

8. The method according to claim 1,
wherein
a container sorting and/or a container inspection is carried out by the image evaluation, which is selected from a group of container inspections which includes a foreign container detection, an equipment inspection, a label inspection, a mouth inspection, a sidewall inspection, a sidewall detection of plastic preforms and the like.

9. The method according to claim 1,
wherein
dimensions for a 360° processing of the container are obtained from the data, wherein these dimensions are selected from a group of dimensions comprising a height of the container, a diameter of the container, a mouth cross-section of the container, a lateral contour of the container, a lateral contour of a mouth region of the container, a lateral contour of a neck of the container and the like.

10. The method according to claim 1,
wherein
a calibration of the model determined on the basis of the data is determined with respect to the captured image.

11. The method according to claim 1,
wherein
data are loaded from a memory device into the evaluation device.

12. The method according to claim 5,
wherein
object points of the 3D model are projected back into the image recording device.

13. The method according to claim 5,
wherein
a contour of the container is generated from a 3D model of the container.

14. An apparatus for inspecting containers, having a transport device which transports the containers along a predetermined transport path, and having an inspection device which inspects the containers, wherein the inspection device having an image recording device which takes at least one spatially resolved image of a container to be inspected, and an image evaluation device is provided which evaluates this image,
wherein
the image evaluation device uses data of a model of this container to evaluate this image.

15. The apparatus according to claim 14,
wherein
the apparatus comprises a model creation device which creates a three-dimensional model of a reference container using the data.
